(19) United States
(12) Patent Application Publication
(10) Pub. No.: US 2026/0122812 A1
(43) Pub. Date: Apr. 30, 2026

(54) Display Device, Method For Manufacturing Display Device And Electronic Device Including Display Device

(71) Applicant: Samsung Display Co., Ltd., Yongin-si (KR)

(72) Inventors: Hyun Jin Song, Yongin-si (KR); Ki Yol Nam, Yongin-si (KR); Won Jae Lee, Yongin-si (KR); Sung Wook Choi, Yongin-si (KR)

(73) Assignee: Samsung Display Co., Ltd., Yongin-si (KR)

(21) Appl. No.: 19/263,671

(22) Filed: Jul. 9, 2025

(30) Foreign Application Priority Data
Oct. 30, 2024 (KR) 10-2024-0150541

(51) Int. Cl. H05K 5/03

(52) U.S. Cl. CPC H05K 5/03

(57) ABSTRACT

A display device includes a display panel, a connection member connected to the display panel, a circuit board connected to the connection member, a driving circuit disposed on the display panel, and a cover member disposed on the display panel to cover a portion of the connection member and the driving circuit.

### CROSS-REFERENCE TO RELATED APPLICATION

This application claims priority from Korean Patent Application No. 10-2024-0150541 filed on Oct. 30, 2024, the entire disclosure of which is hereby incorporated by reference herein.

### BACKGROUND

### 1. Technical Field

The present disclosure relates to a display device, a method for manufacturing a display device, and an electronic device including a display device.

### 2. Background Art

Typically, electronic devices such as smart phones, tablet PCs, digital cameras, laptop computers, navigation devices and smart TVs include an organic light-emitting display device for displaying images.

Organic light-emitting display devices have advantages such as good luminance, low driving voltage, fast response speed and a wide range of color reproduction, and accordingly, such display devices are employed in a variety of devices including smart phones. Existing organic light-emitting display devices may include a display panel having multiple pixels and a circuit unit supplying a signal to the display panel. The display panel may include a signal line transmitting signals for realizing an image and a substrate on which switching elements for driving the pixels are disposed. The circuit unit may include a system supplying a signal and power for realizing an image, a control circuit board including a controller that converts signals supplied from the system into signals to be supplied to the display panel, and a driving circuit board that processes the converted signal from the control circuit board and transmits that signal to the display panel.

To facilitate the above process, the display panel and the driving circuit board may be electrically connected. However, existing approaches for assembly of electronic devices may result in deformation of the display panel. Accordingly, there is a need for improved display devices and methods for the assembly of same.

### BRIEF SUMMARY

Aspects of the present disclosure include providing a display device that is configured to prevent warping of a display panel during a process of bonding a circuit board and a connection member connected to the display panel, providing an electronic device including a display device, and a method for manufacturing a display device.

The above and other aspects of the present disclosure will become more apparent by referencing the embodiments described throughout the present disclosure.

According to one aspect, the present disclosure relates to a display device. A display device may include a display panel, a connection member connected to the display panel, a circuit board connected to the connection member, a driving circuit disposed on the display panel, and a cover member disposed on the display panel to cover a portion of the connection member and the driving circuit.

The cover member may be configured to be disposed on the display panel before the connection member and the circuit board are connected to each other.

The display panel may include a substrate and a display unit disposed on the substrate. Further, the connection member may be connected to the substrate, and the driving circuit and the cover member may be disposed on the substrate.

The driving circuit may be disposed to be closer to the display unit than to the connection member.

The display device may include additional connection members further to the (first) connection member, i.e., the connection member may be provided as a plurality of connection members, and a portion of each connection member of the plurality of connection members may be disposed to be spaced apart from each other in the first direction on the display panel. Similarly, the display device may include additional driving circuits further to the (first) driving circuit, i.e., the driving circuit may be provided as a plurality of driving circuits, and the plurality of driving circuits may be disposed to be spaced apart from each other in the first direction on the display panel. Additionally, the cover member may extend in the first direction on the display panel to cover a portion of each of the plurality of connection members and the plurality of driving circuits.

The plurality of driving circuits may be disposed to be spaced apart from the plurality of connection members in the second direction, the second direction crossing the first direction. The second direction may be transverse to the first direction.

The length of the display panel in the first direction may be greater than an extension length of the cover member in the first direction.

In the cover member, a first accommodating groove may be formed, the first accommodating groove being configured to accommodate a portion of the connection member. Additionally, a second accommodating groove may also be formed in the cover member, the second accommodating groove being configured to accommodate the driving circuit.

According to another aspect of the present disclosure, a method for manufacturing a display device is performed. The method for manufacturing the display device may include preparing a display panel, bonding a driving circuit on the display panel, bonding a portion of a connection member to the display panel, placing a cover member on the display panel to cover the portion of the connection member and the driving circuit, and bonding the connection member and a circuit board.

The driving circuit may include additional driving circuits further to the (first) driving circuit, i.e., the driving circuit may be provided as a plurality of driving circuits. In the bonding of the driving circuit onto the display panel according to this arrangement, the plurality of driving circuits may be bonded to the display panel such that each driving circuit of the plurality of driving circuits is spaced apart from each other in the first direction on the display panel.

The connection member may include additional connection members further to the (first) connection member, i.e., the connection member may be provided as a plurality of connection members. In the bonding of a portion of each connection member of the plurality of connection members to the display panel, a portion of each connection member of the plurality of connection members may be spaced apart from the other connection members of the plurality of connection members in the first direction on the display panel.

In the bonding of a portion of the connection member to the display panel, a portion of each connection member of the plurality of connection members may be bonded to the display panel such that the respective portions are spaced apart from the plurality of driving circuits in the second direction, the second direction crossing the first direction.

In the placement the cover member on the display panel, the cover member may be placed on the display panel to cover a portion of each connection member of the plurality of connection members and the plurality of driving circuits.

When the cover member is placed on the display panel to cover a portion of the connection member and the driving circuit, a first accommodating groove formed in the cover member may be received over a portion of the connection member and a second accommodating groove formed in the cover member may be received over the driving circuit.

According to yet another aspect, the present disclosure relates to an electronic device. An electronic device may include a display panel, a connection member connected to the display panel, a circuit board connected to the connection member, a driving circuit disposed on the display panel, and a cover member placed on the display panel to cover a portion of the connection member and the driving circuit.

The cover member may be configured to be placed on the display panel before the connection member and the circuit board area connected to each other.

The display device may include additional connection members further to the (first) connection member, i.e., the connection member may be provided as a plurality of connection members, and a portion of each connection member of the plurality of connection members may be disposed to be spaced apart in the first direction on the display panel. Similarly, the display device may include additional driving circuits further to the (first) driving circuit, i.e., the driving circuit may be provided as a plurality of driving circuits, and the plurality of driving circuits may be disposed to be spaced apart from each other in the first direction on the display panel. Additionally, the cover member may extend in the first direction on the display panel to cover the portion of each of the plurality of connection members and the plurality of driving circuits.

The plurality of driving circuits may be disposed to be spaced apart from the plurality of connection members in the second direction that crosses the first direction.

The length of the display panel in the first direction may be greater than an extension length of the cover member in the first direction.

In the cover member, a first accommodating groove may be formed, the first accommodating groove being configured to accommodate a portion of a connection member. Additionally, a second accommodating groove may also be formed in the cover member, the second accommodating groove being configured to accommodate a driving circuit.

By arranging a cover member on a display panel so as to cover a portion of a connection member and a driving circuit disposed on the display panel as described herein, it is possible to prevent stress from being applied to the display panel and to prevent warping of the display panel during a process of bonding the connection member and the circuit board.

The advantages according to the aspects of the present disclosure are not limited to those mentioned above and additional advantages may be realized through the aspects of the present disclosure as set forth throughout the present disclosure.

### BRIEF DESCRIPTION OF THE DRAWINGS

The above and other aspects and features of the present disclosure will become more apparent by describing in detail example embodiments thereof with reference to the attached drawings, in which:

FIG. 1 is a plan view of an electronic device according to one embodiment of the present disclosure;

FIG. 2 is a plan view of a display device according to one embodiment of the present disclosure;

FIG. 3 is a plan view of the display device of FIG. 2 with a cover window removed;

FIG. 4 is a plan view of the display device of FIG. 3 with a cover member removed;

FIG. 5 is a cross-sectional view taken along line A-A′ of FIG. 2;

FIG. 6 is an enlarged cross-sectional view of portion B of FIG. 5;

FIG. 7 is a schematic cross-sectional view of the display panel of FIG. 5;

FIG. 8 is a plan view of a step of preparing a display panel in a method for manufacturing a display device according to one embodiment of the present disclosure;

FIG. 9 is a plan view of a step of bonding a driving circuit to the display panel in FIG. 8;

FIG. 10 is a plan view of a step of bonding a portion of a connection member to the display panel in FIG. 9;

FIG. 11 is a plan view of a step of disposing a cover member onto the display panel in FIG. 10; and

FIG. 12 is a diagram of the connection member bonded to the circuit board subsequent to the step in FIG. 11.

### DETAILED DESCRIPTION

Advantages and features of the present disclosure and methods to achieve them will become apparent from the descriptions of example embodiments hereinbelow with reference to the accompanying drawings. However, the present disclosure is not limited to the example embodiments disclosed herein and may be implemented in various ways. The example embodiments are provided for illustrative purposes and for fully conveying the scope of the present disclosure to those skilled in the art.

As used herein, a phrase “an element A on an element B” means that the element A may be disposed directly on the element B and/or that the element A may be disposed indirectly on the element B via another element C, where element C may itself be one or more elements. Like reference numerals denote like elements throughout the present disclosure. The figures, and where applicable, dimensions, ratios, angles, and numbers of elements given in the drawings are merely illustrative and are not limiting.

Although terms such as first, second, etc. are used to distinguish arbitrarily between the elements such terms describe, such terms are not necessarily intended to indicate temporal or other prioritization of such elements. These terms are used to merely distinguish one element from another. Accordingly, as used herein, in some examples, a first element may be a second element within the technical scope of the present disclosure.

It is contemplated that features of various examples of embodiments of the present disclosure may be partially or completely combined. Additionally, various examples of embodiments may be practiced individually or in combination.

Hereinafter, examples of embodiments of the present disclosure will be described in detail with reference to the accompanying drawings.

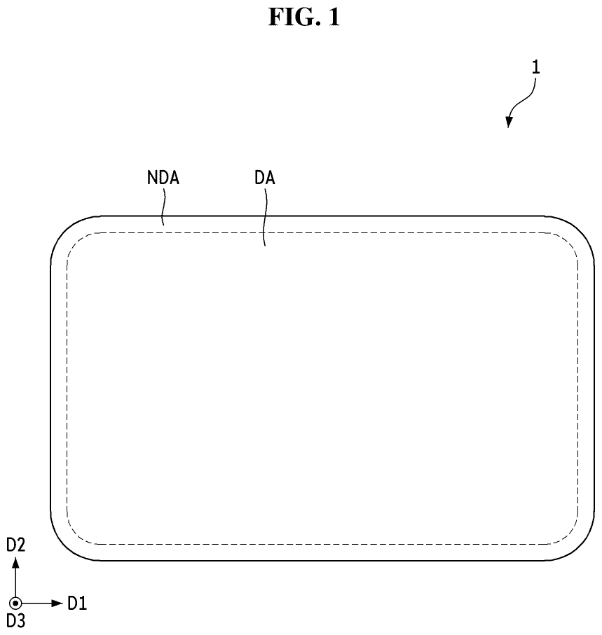

FIG. 1 is a plan view of an electronic device according to one embodiment of the present disclosure.

Referring to FIG. 1, an electronic device 1 may be a variety of electronic devices that provide a display screen. Examples of the electronic device 1 may include, but are not limited to, a mobile phone, a smart phone, a tablet PC, a mobile communications terminal, an electronic organizer, an e-book, a personal digital assistant (PDA), a portable multimedia player (PMP), a navigation device, an ultra mobile PC (UMPC), a television set, a game machine, a wristwatch-type electronic device, a head-mounted display, a personal computer monitor, a laptop computer, a vehicle instrument cluster, a digital camera, a camcorder, an outdoor billboard, an electronic billboard, various medical apparatuses, various inspection devices, various home appliances that include a display area such as a refrigerator and a laundry machine, Internet of things (IoT) devices, etc.

The electronic device 1 may include a display area DA and a non-display area NDA. The shape of the display area DA may be the same as the shape of the electronic device 1 when viewed from the top (or from the front if the electronic device is mounted for viewing purposes, for example). For example, when the electronic device 1 has a rectangular shape when viewed from the top, the display area DA may also have a rectangular shape when viewed from the top. In some examples, the display area may be less than an overall surface area of the electronic device.

The display area DA may include a plurality of pixels configured to display images. The non-display area NDA may be configured so that it does not display images because it does not include pixels. In some examples, the non-display area NDA may be disposed peripherally around the display area DA. While the non-display area NDA may surround the display area DA in some examples, the embodiments of the present disclosure are not limited thereto. In further examples, the display area DA may be only partially surrounded by the non-display area NDA.

The electronic device 1 according to one embodiment of the present disclosure may include a display device 10.

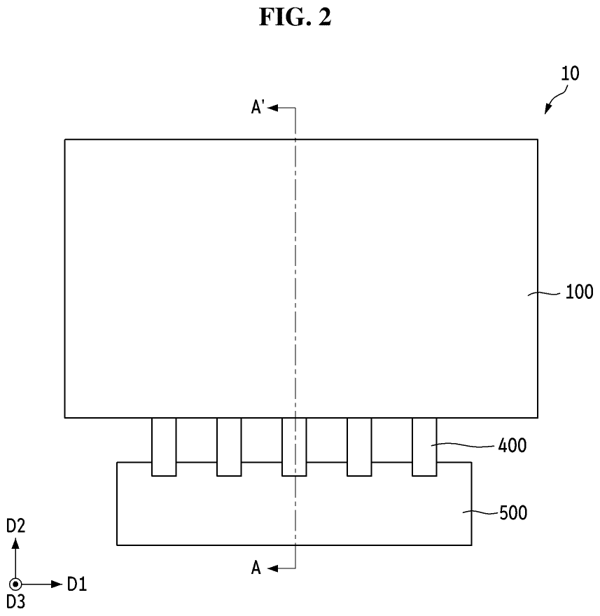

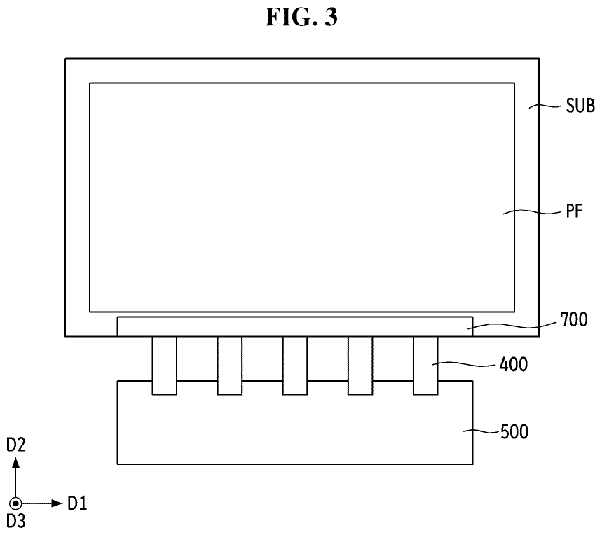

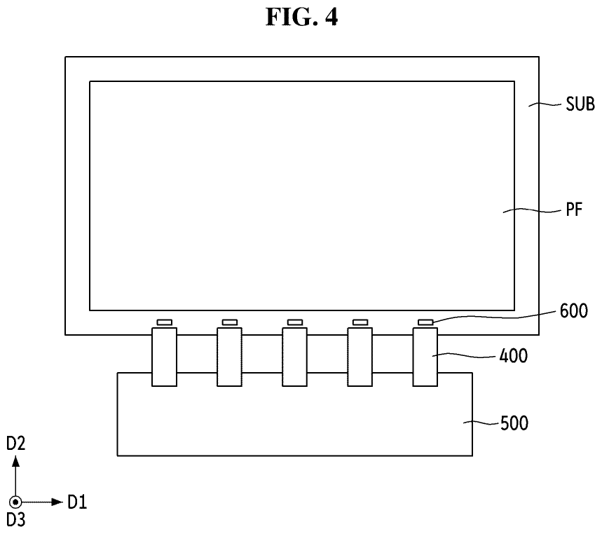

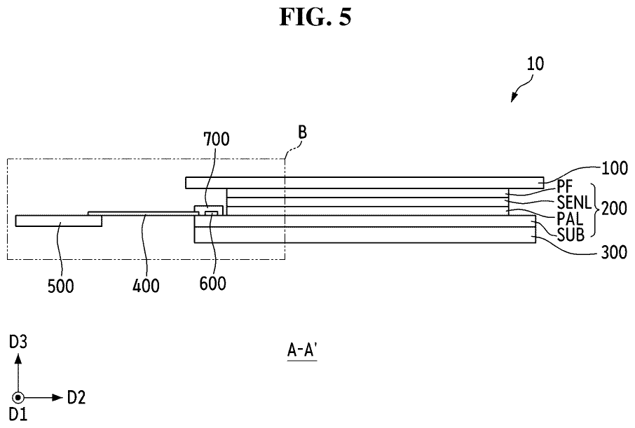

FIG. 2 is a plan view of a display device according to one embodiment of the present disclosure. FIG. 3 is a plan view showing a state in which a cover window included in FIG. 2 is removed. FIG. 4 is a plan view showing a state in which a cover member included in FIG. 3 is removed. FIG. 5 is a cross-sectional view taken along line A-A′ of FIG. 2.

The display device 10 according to one embodiment of the present disclosure is configured for displaying moving images or still images. The display device 10 may be used as the display screen of portable electronic devices such as, but not limited to, a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), as well as the display screen of various other products such as a television, a notebook, a monitor, a billboard and products associated with the Internet of Things. In other examples, the display device 10 may be used as a display screen applied in a vehicle interior, for instance, on a center console.

The display device 10 may be a light-emitting display device such as, but not limited to, an organic light-emitting display device that includes organic light-emitting diodes, a quantum-dot light-emitting display device that includes a quantum-dot light-emitting layer, an inorganic light-emitting display device that includes an inorganic semiconductor, or a micro light-emitting display device that includes micro light-emitting diodes (LED). In the following description, an organic light-emitting display device is described as an example of the display device 10. It is, however, to be understood that the present disclosure is not limited thereto.

A first direction D1 may be parallel to a first side of the display device 10 that is associated with a horizontal direction. For example, the horizontal direction of the display device 10, when viewed from the top, may be parallel to an edge of the display device along a width direction of the display device. A second direction D2 may be parallel to a second side of the display device 10 that is associated with a vertical direction. For example, the vertical direction of the display device 10, when viewed from the top, may be parallel to an edge of the display device along a height direction of the display device. The term “vertical direction” is used to distinguish from “horizontal direction” and signifies a direction that would be vertical if the display device were in an upright position. Throughout the present disclosure, second direction D2 may be referred to as vertical, irrespective of whether the display device 10 is laid down on a ground surface or upright. A third direction D3 may refer to the thickness direction of the display device 10.

The display device 10 may have a quadrangular shape when viewed from the top. Such quadrangular shape may be square or rectangular, among others. For example, the display device 10 may have a shape of a rectangle having longer sides in the first direction D1 and shorter sides in the second direction D2 when viewed from the top. The corners where the longer sides in the first direction D1 meet the shorter sides in the second direction D2 may be rounded with a predetermined curvature or may be sharp and define a right angle. The shape of the display device 10 when viewed from the top is not limited to a quadrangular shape. In some examples, the display device 10 may have another polygonal shape, a circular shape, or an elliptical shape.

Referring to FIGS. 2 to 5, the display device 10 according to one embodiment of the present disclosure includes a cover window 100, a display panel 200, a panel bottom member 300, a connection member 400, a circuit board 500, a driving circuit 600, and a cover member 700.

The cover window 100 may be made of a material with high light transmittance. The cover window 100 may be made of a polymer resin such as polyimide or glass. The cover window 100 may be attached onto a polarizing film PF of the display panel 200 by an adhesive member such as an optically clear adhesive (OCA) film.

Referring to FIG. 5, the display panel 200 may be disposed under the cover window 100. The display panel 200 may have a rectangular shape with longer sides in the first direction D1 and shorter sides in the second direction D2 when viewed from the top. In the display panel 200, the corners where the longer sides in the first direction D1 meet the shorter sides in the second direction D2 may define a right angle or may be rounded with a predetermined curvature. In some examples, the display panel 200 may have a quadrangular shape other than a rectangle, a polygonal shape other than a quadrangular shape, a circular shape, an elliptical shape, or an irregular shape when viewed from the top.

The display panel 200 may include a display area that includes a plurality of emission areas configured to emit light and a non-display area disposed around the display area. The non-display area may surround the display area. A plurality of display pads may be disposed in the non-display area at one edge of the display panel 200.

With continued reference to FIG. 5, the display panel 200 may include a substrate SUB, a display unit PAL, a sensor unit SENL and a polarizing film PF.

The substrate SUB may be made of an insulating material such as, but not limited to, glass, quartz, or a polymer resin. The substrate SUB may be a rigid substrate or a flexible substrate that can be bent, folded, rolled, and so on.

The display unit PAL may be disposed on the substrate SUB. The display unit PAL may be a layer that includes a plurality of emission areas that emit light. The display unit PAL may include a buffer film, a thin-film transistor layer on which thin-film transistors are disposed, a light-emitting element layer that emits light, and an encapsulating layer for encapsulating the light-emitting element layer.

The sensor unit SENL may be disposed on the display unit PAL. The sensor unit SENL may include sensor electrodes and may be configured to detect whether there is contact with the display panel, e.g., whether a user has touched the display panel.

The polarizing film PF may be disposed on the sensor unit SENL. The polarizing film PF can prevent the deterioration of image visibility of the display panel 200 due to reflection of external light. The polarizing film PF may include a linear polarizer and a phase retardation film such as a λ/4 (quarter-wave) plate. The phase retardation film may be disposed on the sensor unit SENL, and the linear polarizer may be disposed on the phase retardation film. The cover window 100 may be disposed on the polarizing film PF.

With continued reference to FIG. 5, the panel bottom member 300 may be disposed under the substrate SUB such that the panel bottom member 300 is on one side of the display panel 200. In some examples, the panel bottom member 300 may be attached to the lower surface of the substrate SUB by an adhesive layer (not illustrated). The adhesive layer (not illustrated) may be a pressure-sensitive adhesive (PSA). The panel bottom member 300 may include at least one of: a light-absorbing member for absorbing incoming light from outside the display device, a buffer member for absorbing external impact, and a heat dissipating member for efficiently discharging heat from the display panel 200.

The light-absorbing member may be disposed under the substrate SUB. The light-absorbing member is configured to block the transmission of light to prevent the elements disposed thereunder from being seen from a top side of the display panel 200, such as from the circuit board 500. The light-absorbing member may include a light-absorbing material such as a black pigment and a black dye.

The buffer member may be disposed under the light-absorbing member. The buffer member is configured to absorb an external impact to prevent the display panel 200 from being damaged. The buffer member may be made up of a single layer or multiple layers. In some examples, the buffer member may be formed of a polymer resin such as polyurethane, polycarbonate, polypropylene or polyethylene, or may be formed of a material having elasticity such as a rubber or a sponge. A foaming process applied to a urethane-based material or an acrylic-based material may be used to create a sponge.

The heat dissipating member may be disposed under the buffer member. The heat dissipating member may include a first heat dissipation layer including graphite or carbon nanotubes, and a second heat dissipation layer formed of a thin metal film such as copper, nickel, ferrite or silver. The heat dissipating member can block electromagnetic waves and have high thermal conductivity.

Referring to FIGS. 4 and 5, the connection member 400 may be connected to the display panel 200. In some embodiments, the connection member 400 may be connected to a plurality of display pads of the display panel 200 by a thermal bonding or through a conductive bonding member such as an anisotropic conductive film. For example, one side of the connection member 400 may be bonded to the plurality of display pads disposed on a substrate SUB of the display panel 200. Through this arrangement, the display panel 200 and the connection member 400 may be electrically connected.

In some embodiments, a display device 10 may include a single connection member 400. In other embodiments, such as the embodiment shown in FIGS. 2-5, a display device 10 may include more than one connection member 400. As shown in FIG. 4, a plurality of connection members 400 may be connected to the display panel 200. In this example, one side of each connection member of the plurality of connection members 400 may be disposed on the substrate SUB such that each connection member of the plurality of connection members is spaced apart from the others in the first direction D1. Further, one side of each connection member of the plurality of connection members 400 may be bonded to the substrate SUB such that each connection member of the plurality of connection members is spaced apart from the others on the substrate SUB. In the above described examples, a portion of the connection member 400 representing less than an entire length of the connection member 400 is disposed and bonded onto the substrate SUB.

In some examples, the plurality of connection members 400 may be a flexible printed circuit board or a chip on film.

The circuit board 500 may be connected to the plurality of connection members 400 of the display device 10. In some embodiments, the circuit board 500 may be connected to the plurality of connection members 400 by a thermal bonding or through a conductive bonding member such as an anisotropic conductive film. For example, the circuit board 500 may be bonded to a side of each connection member of the plurality of connection members 400 so that the plurality of circuit pads disposed on the circuit board 500 are connected to the plurality of connection members 400. Due to this, the connection member 400 and the circuit board 500 may be electrically connected. In some embodiments, one or more aspects of the above-described connection of the circuit board 500 may be applied to any one or more connection members 400.

When the connection member 400 is bent, the circuit board 500 may overlap the panel bottom member 300. The circuit board 500 may be a flexible printed circuit board (FPCB) that is bendable, a rigid printed circuit board (PCB) that is rigid and not bendable, or a hybrid printed circuit board including a rigid printed circuit board and a flexible printed circuit board.

The circuit board 500 may process the converted signal in a control circuit board and transmit such signal to the display panel 200. The circuit board 500 may be electrically connected to the display panel 200 by the connection member 400.

The driving circuit 600 may be disposed on the display panel 200. The driving circuit 600 may receive control signals and power voltages through the circuit board 500 and generate and output signals and voltages for driving the display panel 200. The driving circuit 600 may be formed as an integrated circuit (IC) and may be connected to the circuit board 500.

The driving circuit 600 may be bonded to the substrate SUB of the display panel 200 by thermal bonding or through a conductive bonding member such as an anisotropic conductive film. In some embodiments, the driving circuit 600 is a single driving circuit 600. In other embodiments, such as the embodiment shown in FIGS. 2-5, the driving circuit 600 may include more than one driving circuit. As shown in FIG. 4, a plurality of driving circuits 600 may be disposed on the substrate SUB such that each driving circuit of the plurality of driving circuits 600 is spaced apart from the others in the first direction D1. Further, the plurality of driving circuits 600 may be bonded to the substrate SUB such that each driving circuit of the plurality of driving circuits 600 is spaced apart in the first direction D1 on the substrate SUB.

In some examples, each driving circuit of the plurality of driving circuits 600 may be disposed on the substrate SUB so that the driving circuits are closer to the display unit PAL than the plurality of connection members 400. For example, the plurality of driving circuits 600 may be spaced apart from the display unit PAL and the plurality of connection members 400 in the second direction D2, which is a direction perpendicular to the first direction D1, and be disposed closer to the display unit PAL than the connection members 400.

The cover member 700 may be disposed on the display panel 200 to cover a portion of the plurality of connection members 400 and each driving circuit of the plurality of driving circuits 600. For example, as shown in FIG. 3, the cover member 700 may have a length that extends in the first direction D1 on the substrate SUB to cover a portion of each connection member of the plurality of connection members 400 and an entirety of each driving circuit of the plurality of driving circuits 600. In some examples, the cover member 700 may cover the same portion of each connection member of the plurality of connection members 400 as the portion that is bonded to the display panel 200, as shown in FIG. 5, for example. In other examples, the cover member 700 may cover less of each connection member 400 than the portion of the respective connection members 400 that are bonded to the display panel 200.

The length of the cover member 700 in the first direction D1 may be shorter than the length of the display panel 200 in the first direction D1. In some embodiments, a first side of the cover member 700 and a second side of the cover member 700 opposite the first side, where the length of the cover member 700 extends from the first side to the second side in the first direction D1, may be located on the substrate SUB of the display panel 200.

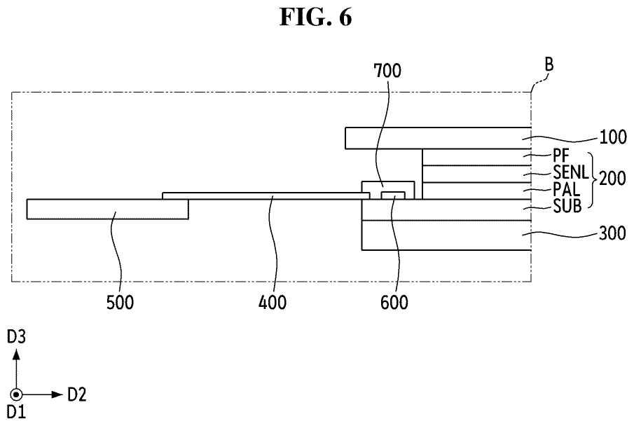

FIG. 6 is an enlarged view of portion B of FIG. 5. In FIG. 6, a first accommodating groove and a second accommodating groove are defined in the cover member 700.

When the cover member 700 is disposed on the substrate SUB to cover a portion of each connection member of the plurality of connection members 400 and the plurality of driving circuits 600, the first accommodating groove may accommodate, and the first accommodating groove is sized to accommodate, a portion of each connection member of the plurality of connection members 400. In some examples, the cover member 700 may define the first accommodating groove in a number commensurate with a number of the plurality of connection members 400. For instance, where display device 10 includes five connection members 400, the cover member 700 may define five of the first accommodating groove.

When the cover member 700 is disposed on the substrate SUB to cover a portion of the plurality of connection members 400 and the plurality of driving circuits 600, the second accommodating groove may accommodate, and the second accommodating groove is sized to accommodate, the plurality of driving circuits 600. In some examples, the cover member 700 may define the second accommodating groove in a number commensurate with a number of the plurality of driving circuits 600. For instance, where display device 10 includes five driving circuits 600, the cover member 700 may define five of the second accommodating groove.

Before the plurality of connection members 400 and the circuit board 500 are connected, the cover member 700 may be disposed on the substrate SUB of the display panel 200. For example, the cover member 700 may be disposed on the substrate SUB of the display panel 200 to cover a portion of the plurality of connection members 400 and the plurality of driving circuits 600 after the plurality of driving circuits 600 and a portion of the plurality of connection members 400 are sequentially bonded on the substrate SUB of the display panel 200. In this way, because the cover member 700 covers a portion of the plurality of connection members 400 and the plurality of driving circuits 600 on the substrate SUB of the display panel 200 before the plurality of connection members 400 and the circuit board 500 are thermally bonded, it is possible to prevent stress that occurs during the process of thermally bonding the plurality of connection members 400 to the circuit board 500 from being transmitted to the display panel 200. Accordingly, the contemplated arrangements of the display device 10 prevent warpage from occurring in the display panel 200.

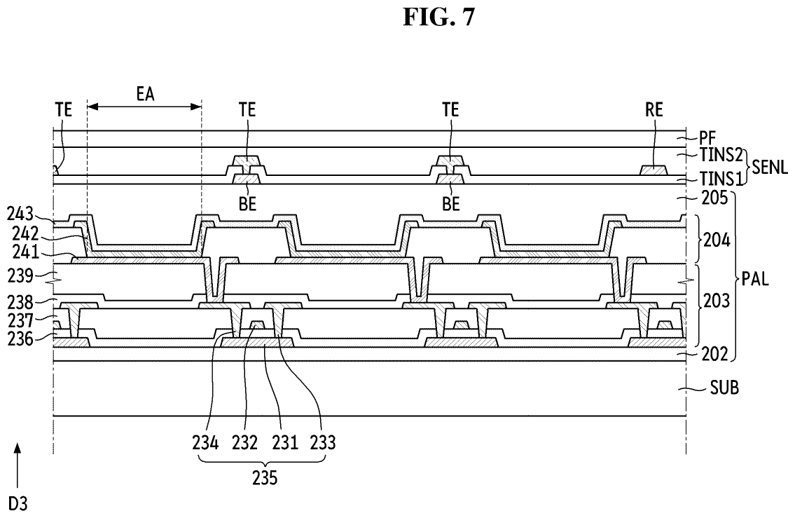

FIG. 7 is a cross-sectional view that shows a schematic representation of the display panel of FIG. 5. In FIG. 7, the display unit PAL includes a buffer film 202, a thin-film transistor layer 203, a light-emitting element layer 204, and an encapsulation layer 205. It should be appreciated that the components of the display panel shown in FIG. 7 are one example arrangement and are not limiting.

The buffer film 202 may be formed on the substrate SUB. The buffer film 202 may be formed on the substrate SUB to protect thin-film transistors 235 and light-emitting elements from moisture permeating through the substrate SUB, the substrate SUB being susceptible to moisture permeation. The buffer film 202 may be formed of multiple inorganic layers alternately stacked. For example, the buffer film 202 may be formed of multiple films in which one or more inorganic films of a silicon oxide film SiOx, a silicon nitride film SiNx, and a silicon oxynitride film are alternately stacked. In some examples, the buffer film 202 may be omitted from the display unit PAL.

The thin-film transistor layer 203 may be disposed on the buffer film 202. The thin-film transistor layer 203 includes the thin-film transistors 235, a gate insulating film 236, an interlayer insulating film 237, a protective film 238, and an organic film 239.

Each of the thin-film transistors 235 includes an active layer 231, a gate electrode 232, a source electrode 233, and a drain electrode 234. In the arrangement shown in FIG. 7, the thin-film transistor 235 is formed in a top gate manner in which the gate electrode 232 is located on top of the active layer 231, but it should be noted that the present disclosure is not limited thereto. That is, the thin-film transistors 235 may be formed in a bottom gate manner in which the gate electrode 232 is located on a bottom side of the active layer 231, or a double gate manner in which the gate electrode 232 is located on both of the top and bottom sides of the active layer 231.

The active layer 231 is formed on the buffer film 202. The active layer 231 may be formed of a silicon-based semiconductor material or an oxide-based semiconductor material. For example, the active layer 231 may be formed of a poly silicon, an amorphous silicon, or an oxide semiconductor. A light blocking layer for blocking external light that would otherwise be received on the active layer 231 may be formed between the buffer film 202 and the active layer 231.

The gate insulating film 236 may be formed on the active layer 231. The gate insulating film 236 may be formed of an inorganic film. For example, the gate insulating film 236 may be formed of a silicon oxide film (SiOx), a silicon nitride film (SiNx), or a multiple film thereof.

The gate electrode 232 may be formed on the gate insulating film 236. The gate electrode 232 and a gate line may be formed as a single layer or multiple layers. In some examples, the gate electrode 232 may be made of any one of molybdenum (Mo), aluminum (Al), chromium (Cr), gold (Au), titanium (Ti), nickel (Ni), neodymium (Nd) and copper (Cu) or an alloy thereof.

The interlayer insulating film 237 may be formed on the gate electrode 232 and the gate line. The interlayer insulating film 237 may be formed of an inorganic film, for example, a silicon oxide film (SiOx), a silicon nitride film (SiNx), or a film based on a combination thereof.

The source electrode 233 and the drain electrode 234 may be formed on the interlayer insulating film 237. Each of the source electrode 233 and the drain electrode 234 may be connected to the active layer 231 through a contact hole penetrating the gate insulating film 236 and the interlayer insulating film 237. Each of the source electrode 233 and the drain electrode 234 may be formed as a single layer or multiple layers. In some examples, the source electrode 233 and the drain electrode 234 may be made of any one of molybdenum (Mo), aluminum (Al), chromium (Cr), gold (Au), titanium (Ti), nickel (Ni), neodymium (Nd) and copper (Cu) or an alloy thereof.

The protective film 238 for insulating the thin-film transistors 235 may be formed on the source electrode 233 and the drain electrode 234. In some examples, the protective film 238 may be formed of an inorganic film, for example, a silicon oxide film (SiOx), a silicon nitride film (SiNx), or a film based on a combination thereof.

The organic film 239 for planarizing a step due to the thin-film transistor 235 may be formed on the protective film 238. In some examples, the organic film 239 may be formed of an organic film such as acryl resin, epoxy resin, phenolic resin, polyamide resin, polyimide resin and the like.

The light-emitting element layer 204 is formed on the thin-film transistor layer 203. The light-emitting element layer 204 includes the light-emitting elements and a bank. The light-emitting elements and the bank are formed on the organic film 239. The light-emitting element may be an organic light-emitting element that includes an anode electrode 241, light-emitting layers 242, and a cathode electrode 243.

The anode electrode 241 may be formed on the organic film 239. The anode electrode 241 may be connected to the source electrode 233 of the thin-film transistor 235 through a contact hole penetrating the protective film 238 and the organic film 239.

The bank may be formed to cover the edge of the anode electrode 241 on the organic film 239 to partition emission areas EA of pixels. Put another way, the bank serves to define the emission areas EA of pixels. Each of the pixels, in which the anode electrode 241, the light-emitting layer 242, and the cathode electrode 243 are sequentially stacked, indicates an area in which holes from the anode electrode 241 and electrons from the cathode electrode 243 are combined with each other in the light-emitting layer 242 to emit light.

The light-emitting layer 242 is formed on the anode electrode 241 and the bank. The light-emitting layer 242 may be an organic light-emitting layer. The light-emitting layer 242 may emit one of red light, green light and blue light. Alternatively, in some examples, the light-emitting layer 242 may be a white light-emitting layer that emits white light. In this case, the light-emitting layer 242 may have a structure in which a red light-emitting layer, a green light-emitting layer, and a blue light-emitting layer are stacked, and such layers may be common layers formed commonly to the pixels. When the light-emitting layer 242 is a white light-emitting layer with stacked red, green and blue layers, the display panel 200 may further include a separate color filter for displaying a red, green or blue color.

The light-emitting layer 242 may include a hole transporting layer, a light-emitting layer, and an electron transporting layer. In addition, the light-emitting layer 242 may be formed in a tandem structure of two or more stacks, in which case a charge generating layer may be formed between the stacks.

The cathode electrode 243 is formed on the light-emitting layer 242. The cathode electrode 243 may be formed to cover the light-emitting layer 242. The cathode electrode 243 may be a common layer formed commonly to the pixels. Put another way, the cathode electrode 243 may be a single layer that encompasses all of the pixels of the display.

In a case where the light-emitting element layer 204 is formed by a top emission method in which light is emitted upward, the anode electrode 241 may be formed of a metal material having high reflectivity. In some examples, the anode electrode 241 may be made up of one of a stacked structure (Ti/Al/Ti) of aluminum and titanium, a stacked structure (ITO/Al/ITO) of aluminum and Indium Tin Oxide (ITO), an alloy of silver (Ag), palladium (Pd) and copper (Cu) (APC alloy), and a stacked structure (ITO/APC/ITO) of an APC alloy and ITO, or the like. Further, the cathode electrode 243 may be formed of a transparent conductive material (TCO) such as ITO or zinc-doped indium oxide (IZO) that can transmit light or a semi-transmissive conductive material such as magnesium (Mg), silver (Ag), or an alloy of magnesium (Mg) and silver (Ag). In a case where the cathode electrode 243 is formed of a semi-transmissive conductive material, the light emission efficiency may be increased due to a micro-cavity effect.

In a case where the light-emitting element layer 204 is formed by a bottom emission method in which light is emitted downward, the anode electrode 241 may be formed of a transparent conductive material (TCO) such as ITO or IZO or a semi-transmissive conductive material such as magnesium (Mg), silver (Ag), or an alloy of magnesium (Mg) and silver (Ag). The cathode electrode 243 may be formed of a metal material, having high reflectivity. In some examples, the cathode electrode 243 may be made up of one of a stacked structure (Ti/Al/Ti) of aluminum (Al) and titanium (Ti), a stacked structure (ITO/Al/ITO) of Al and ITO, an APC alloy, a stacked structure (ITO/APC/ITO) of an APC alloy and ITO, or the like. In a case where the anode electrode 241 is formed of a semi-transmissive conductive material, the light emission efficiency may be increased due to a micro-cavity effect.

The encapsulation layer 205 is formed on the light-emitting element layer 204. The encapsulation layer 205 serves to prevent air or moisture from permeating the light-emitting layer 242 and the cathode electrode 243. To this end, the encapsulation layer 205 may further comprise at least one inorganic film. The inorganic film may be formed of, for example, silicon nitride, aluminum nitride, zirconium nitride, titanium nitride, hafnium nitride, tantalum nitride, silicon oxide, aluminum oxide, or titanium oxide. In addition, the encapsulation layer 205 may further include at least one organic film. The inorganic film may have a thickness sufficient to prevent particles from penetrating the encapsulation layer 205 and entering the light-emitting layer 242 and the cathode electrode 243.

The sensor unit SENL may be formed on the encapsulation layer 205. In examples where the sensor unit SENL is formed directly on the encapsulation layer 205, the thickness of the display device 10 may be reduced compared with a display device where a separate touch panel is attached on the encapsulation layer 205.

The sensor unit SENL may include sensor electrodes for sensing a user's touch by a capacitive manner, and touch lines connecting the pads and the sensor electrodes. For example, the sensor unit SENL can sense a user's touch by self-capacitance sensing or mutual capacitance sensing. In the example shown in FIG. 7, the sensor unit SENL is made up of two layers including driving electrodes TE, sensing electrodes RE and bridges BE connecting between the driving electrodes TE for mutual capacitance sensing.

The bridges BE may be formed on the encapsulation layer 205. The bridges BE may be made up of, but are not limited to, a stack structure of aluminum and titanium (Ti/Al/Ti), a stack structure of aluminum and ITO (ITO/Al/ITO), an APC alloy and a stack structure of APC alloy and ITO (ITO/APC/ITO). In some examples, the bridges BE may be made up of a single layer of molybdenum (Mo), titanium (Ti), copper (Cu), aluminum (Al) or ITO.

A first sensing insulating film TINS1 is formed over the bridges BE. The first sensing insulating film TINS1 may be formed of an inorganic film, for example, a silicon nitride layer, a silicon oxynitride layer, a silicon oxide layer, a titanium oxide layer, or an aluminum oxide layer.

The driving electrodes TE and the sensing electrodes RE may be formed on the first sensing insulating film TINS1. The driving electrode TE and the sensing electrode RE may be formed as, but are not limited to, a stack structure of aluminum and titanium (Ti/Al/Ti), a stack structure of aluminum and ITO (ITO/AI/ITO), an APC alloy and a stack structure of APC alloy and ITO (ITO/APC/ITO). In some examples, the driving electrodes TE and the sensing electrodes RE may be made up of a single layer of molybdenum (Mo), titanium (Ti), copper (Cu), aluminum (Al) or ITO.

Contact holes may be formed in the first sensing insulating film TINS1 which penetrate the first sensing insulating film TINS1 to expose the bridges BE. The driving electrodes TE may be connected to the bridges BE through the contact holes.

A second sensing insulating film TINS2 is formed over the driving electrodes TE and the sensing electrodes RE. The second sensing insulating film TINS2 may provide a flat surface over the driving electrodes TE, the sensing electrodes RE and the bridges BE which have different heights. The second sensing insulating film TINS2 may be formed of an organic film such as one of an acryl resin, an epoxy resin, a phenolic resin, a polyamide resin and a polyimide resin.

The bridges BE connecting between the adjacent driving electrodes TE may be disposed on the encapsulation layer 205, and the driving electrodes TE and the sensing electrodes RE may be disposed on the first sensing insulating film TINS1. Accordingly, the driving electrodes TE and the sensing electrodes RE may be electrically separated from each other at their intersections, while the sensing electrodes RE may be electrically connected with one another in a first direction, and the driving electrodes TE may be electrically connected with one another in a second direction different from the first direction.

The polarizing film PF may be disposed on the second sensing insulating film TINS2 and is configured to prevent the deterioration of image visibility of the display panel 200 due to reflection of external light.

In some embodiments, a standalone display device 10 is contemplated. For example, it is contemplated that any display device 10 contemplated by the present disclosure may, in some embodiments, be a standalone display device 10. In other embodiments, an electronic device 1 including a display device 10 is contemplated. It is contemplated that any display device 10 contemplated by the present disclosure may be incorporated into any electronic device 1 contemplated by the present disclosure. Further, in any of these embodiments, any combination of features contemplated for the display device 10 may be included.

Hereinafter, a method for manufacturing a display device according to one embodiment of the present disclosure will be described with reference to the drawings.

A method for manufacturing a display device according to one embodiment of the present disclosure may include one or more of retrieving the display panel 200, preparing the display panel 200, bonding the driving circuit 600 on the display panel 200, bonding a portion of the connection member 400 to the display panel 200, placing the cover member 700 on the display panel 200 to cover a portion of the connection member 400 and the driving circuit 600, and bonding the connection member 400 and the circuit board 500.

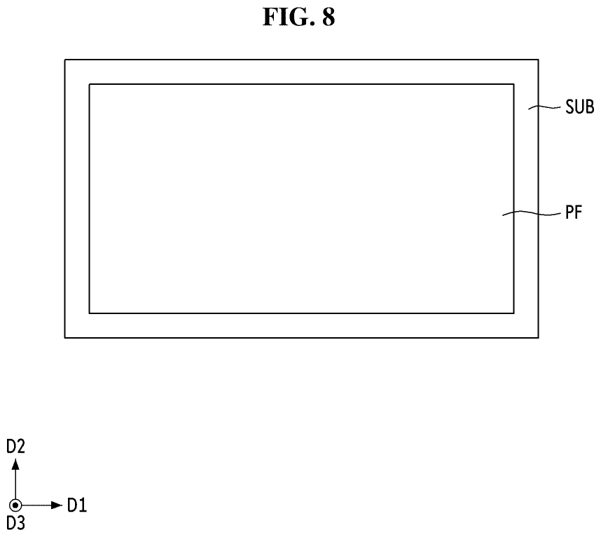

FIG. 8 is a plan view showing a step of preparing a display panel after retrieval in a method for manufacturing a display device according to one embodiment of the present disclosure. In some alternative examples, preparation steps are completed prior to retrieval of the display panel and the performance of the method.

Referring to FIG. 8, in the preparation of the display panel 200, the cover window 100 is removed from the polarizing film PF.

In some embodiments, the display panel 200 is prepared before the cover window 100 is disposed on the polarizing film PF. The display panel 200 is prepared before the cover window 100 to more easily bond a portion of the plurality of connection members 400 and the plurality of driving circuits 600 onto the substrate SUB of the display panel 200. Although the present embodiment contemplates that a portion of the plurality of connection members 400 and the plurality of driving circuits 600 are bonded to the display panel 200 before the cover window 100 is disposed on the polarizing film PF, the present disclosure is not limited thereto. For example, a portion of the plurality of connection members 400 and the plurality of driving circuits 600 may be bonded to the display panel after the cover 100 is disposed on the polarizing film PF.

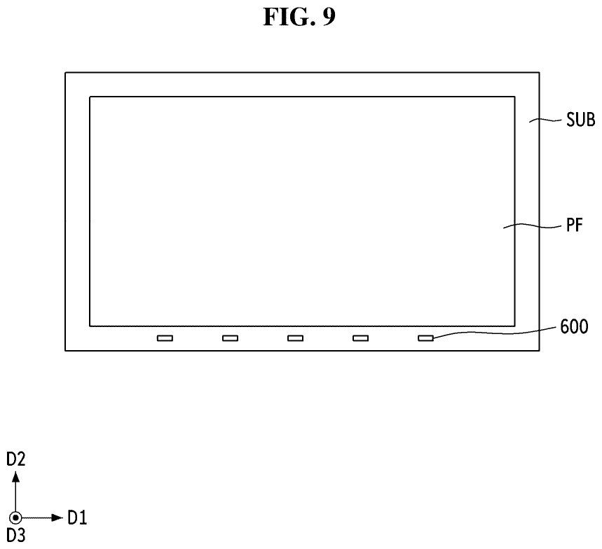

Another step in the method involves bonding the plurality of drive circuits 600 to the display panel. FIG. 9 is a plan view showing a state in which a driving circuit is bonded to the display panel of FIG. 8. In FIG. 9, the plurality of driving circuits 600 may be bonded onto the substrate SUB of the display panel 200. For example, the plurality of driving circuits 600 may be bonded to the substrate SUB such that each driving circuit of the plurality of driving circuits are spaced apart from each other in the first direction D1 on the substrate SUB. The plurality of driving circuits 600 may be bonded on the substrate SUB of the display panel 200 by a thermal bonding technique or through a conductive bonding member such as an anisotropic conductive film.

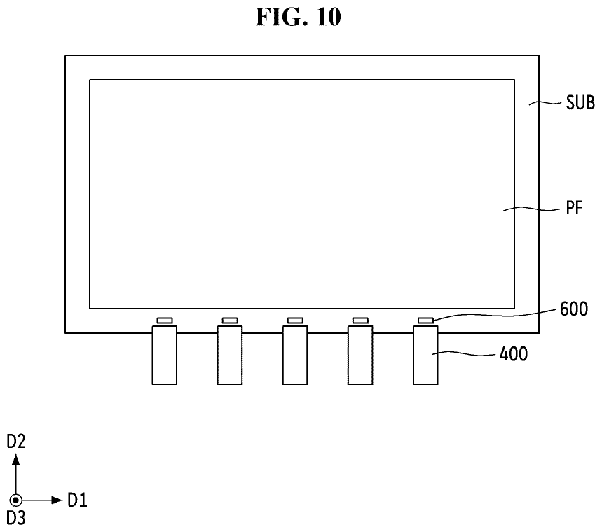

Yet another step in the method involves bonding the plurality of connection members 400 to the display panel. FIG. 10 is a plan view showing a state in which a portion of a connection member is bonded to the display panel of FIG. 9. In FIG. 10, a portion of each connection member of the plurality of connection members 400 may be bonded on the substrate SUB of the display panel 200. For example, a portion of each connection member of the plurality of connection members 400 may be bonded to the substrate SUB such that each connection member is spaced apart from each other in the first direction D1 on the substrate SUB. The portion of each connection member of the plurality of connection members 400 may be spaced apart in the second direction D2 from the plurality of driving circuits 600 and may be closer to the circuit board 500 than the plurality of driving circuits 600. The portion of each connection member of the plurality of connection members 400 may be bonded on the substrate SUB of the display panel 200 by a thermal bonding technique or through a conductive bonding member such as an anisotropic conductive film.

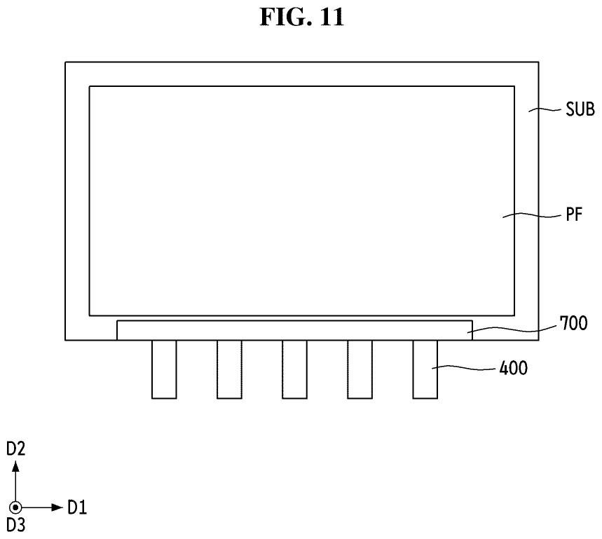

FIG. 11 is a plan view showing a state in which a cover member is disposed on the display panel of FIG. 10 according to another step in the method. In FIG. 11, the cover member 700 may be disposed on the substrate SUB of the display panel 200 to cover a portion of each of the plurality of connection members 400 and the plurality of driving circuits 600. For example, the cover member 700 may extend in the first direction D1 on the substrate SUB of the display panel 200 to cover a portion of each connection member of the plurality of connection members 400 and the plurality of driving circuits 600. As shown in FIG. 11 of the depicted method, cover member 700 covers each driving circuit of the plurality of driving circuits 600 in their entirety. The length of the cover member 700 in the first direction D1 may be shorter than the length of the display panel 200 in the first direction D1. In some embodiments, opposing sides, i.e., ends of the cover member 700 in the first direction D1 may be disposed on the substrate SUB of the display panel 200.

When the cover member 700 is disposed on the substrate SUB of the display panel 200 to cover a portion of each connection member of the plurality of connection members 400 and the plurality of driving circuits 600, a portion of each connection member of the plurality of connection members 400 may be accommodated within the first accommodating groove of the cover member 700, and the plurality of driving circuits 600 may be accommodated within the second accommodating groove of the cover member 700.

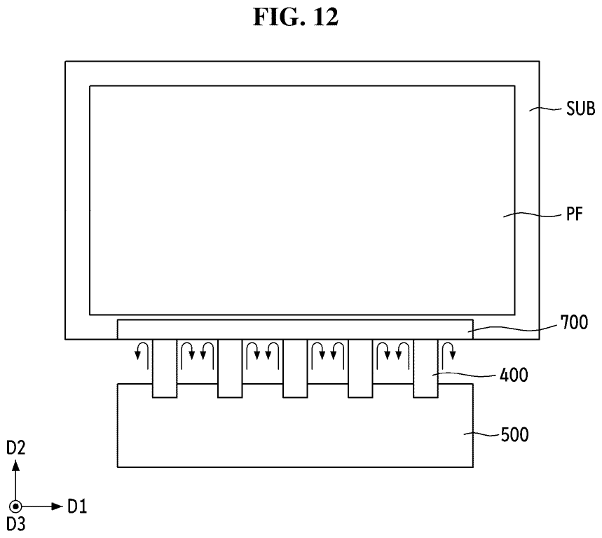

FIG. 12 is a diagram showing a state in which a connection member and a circuit board are bonded according to another step in the method. In FIG. 12, an end of each of the plurality of connection members 400 opposite an end bonded to the display panel 200 is bonded to the circuit board 500. The plurality of connection members 400 and the circuit board 500 may be bonded by a thermal bonding technique or through a conductive bonding member such as an anisotropic conductive member. When the plurality of connection members 400 and the circuit board 500 are thermally bonded, stress may occur in the process of bonding the plurality of connection members 400 and the circuit board 500. Without an adequate protective arrangement, such stress may be transmitted and otherwise applied to the display panel, which may cause deformation and warping to occur in the display panel. However, in the present methods, because the cover member 700 covers a portion of each connection member of the plurality of connection members 400 and the plurality of driving circuits 600 on the substrate SUB of the display panel 200 before the plurality of connection members 400 and the circuit board 500 are thermally bonded, stress that occurs in the process of thermally bonding the plurality of connection members 400 to the circuit board 500 may be prevented from being transmitted and otherwise applied to the display panel 200. Accordingly, deformation and warping of the display panel 200 may be prevented from occurring.

In some embodiments, the method may be performed using one or more connection members 400 and one or more driving circuits 600. In this manner, the manufactured display device 10 may include as few as one connection member 400 and as few as one driving circuit 600.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

1. A display device comprising:
a display panel;
a connection member connected to the display panel;
a circuit board connected to the connection member;
a driving circuit disposed on the display panel; and
a cover member disposed on the display panel to cover a portion of the connection member and the driving circuit.

2. The display device of claim 1,
wherein the cover member is configured to be disposed on the display panel before the connection member and the circuit board are connected to each other.

3. The display device of claim 1,
wherein the display panel further comprises:
a substrate; and
a display unit disposed on the substrate,
wherein the connection member is connected to the substrate, and
the driving circuit and the cover member are disposed on the substrate.

4. The display device of claim 3,
wherein the driving circuit is disposed on the substrate such that the driving circuit is closer to the display unit than to the connection member.

5. The display device of claim 1, wherein the connection member is a first connection member and the driving circuit is a first driving circuit, the display device further comprising:
a plurality of connection members, the portion of the first connection member and a portion of each connection member of the plurality of connection members being disposed on the display panel spaced apart from each other along a first direction,
a plurality of driving circuits, the first driving circuit and each driving circuit of the plurality of driving circuits being disposed on the display panel spaced apart from each other along the first direction, and
wherein the cover member extends in the first direction on the display panel to cover the portion of the first connection member, the portion of each connection member of the plurality of connection members, the first driving circuit and each driving circuit of the plurality of driving circuits.

6. The display device of claim 5,
wherein the first driving circuit and the plurality of driving circuits are spaced apart from the first connection member and the plurality of connection members in a second direction transverse to the first direction.

7. The display device of claim 5,
wherein a length of the display panel in the first direction is greater than a length of the cover member in the first direction.

8. The display device of claim 1,
wherein the cover member defines a first accommodating groove sized to accommodate the portion of the connection member and a second accommodating groove sized to accommodate the driving circuit.

9. A method for manufacturing a display device, the method comprising:
retrieving a display panel;
bonding a driving circuit onto the display panel;
bonding a portion of a connection member to the display panel;
placing a cover member on the display panel to cover the portion of the connection member and the driving circuit; and
bonding the connection member to a circuit board.

10. The method of claim 9, wherein the driving circuit is a first driving circuit, and the method further comprises:
bonding a plurality of driving circuits onto the display panel such that the plurality of driving circuits are spaced apart from each other and the first driving circuit in a first direction.

11. The method of claim 10, wherein the connection member is a first connection member, and the method further comprises:
bonding a portion of each connection member of a plurality of connection members to the display panel such that the portion of each connection member of the plurality of connection members is spaced apart from the other portions of the plurality of connection members and the portion of the first connection member in the first direction.

12. The method of claim 11,
wherein the bonding of the portion of the first connection member and the portion of each connection member of the plurality of connection members to the display panel results in the first connection member and
the plurality of connection members being spaced apart from the first driving circuit and the plurality of driving circuits in a second direction transverse to the first direction.

13. The method of claim 11,
wherein placing the cover member on the display panel further comprises placing the cover member on the display panel to cover the portion of the first connection member, the portion of each connection member of the plurality of connection members, the first driving circuit and the plurality of driving circuits.

14. The method of claim 9,
wherein placing the cover member on the display panel further comprises placing the cover member on the display panel such that a first accommodating groove defined by the cover member is positioned over the portion of the connection member, and a second accommodating groove defined by the cover member is positioned over the driving circuit.

15. An electronic device comprising:
a display panel;
a connection member connected to the display panel;
a circuit board connected to the connection member;
a driving circuit disposed on the display panel; and
a cover member disposed on the display panel to cover a portion of the connection member and the driving circuit.

16. The electronic device of claim 15,
wherein the cover member is configured to be placed on the display panel before the connection member and the circuit board are connected to each other.

17. The electronic device of claim 15, wherein the connection member is a first connection member and the driving circuit is a first driving circuit, the electronic device further comprising:
a plurality of connection members, the portion of the first connection member and a portion of each connection member of the plurality of connection members being disposed on the display panel spaced apart from each other along a first direction,
a plurality of driving circuits, the first driving circuit and each driving circuit of the plurality of driving circuits being disposed on the display panel spaced apart from each other along a first direction, and
wherein the cover member extends in the first direction on the display panel to cover the portion of the first connection member, the portion of each connection member of the plurality of connection members, the first driving circuit and each driving circuit of the plurality of driving circuits.

18. The electronic device of claim 17,
wherein the first driving circuit and the plurality of driving circuits are spaced apart from the first connection member and the plurality of connection members in a second direction transverse to the first direction.

19. The electronic device of claim 17,
wherein a length of the display panel in the first direction is greater than a length of the cover member in the first direction.

20. The electronic device of claim 15,
wherein the cover member defines
a first accommodating groove sized to accommodate the portion of the connection member and
a second accommodating groove sized to accommodate the driving circuit.
